(19) United States
(12) Patent Application Publication
(10) Pub. No.: US 2023/0215996 A1
(43) Pub. Date: Jul. 6, 2023

(54) LIGHT-EMITTING DEVICE AND DISPLAY DEVICE

(71) Applicant: KYOCERA Corporation, Kyoto-shi, Kyoto (JP)

(72) Inventor: Masaya TAMAKI, Yokohama-shi, Kanagawa (JP)

(21) Appl. No.: 17/927,564

(22) PCT Filed: May 10, 2021
(86) PCT No.: PCT/JP2021/017743

§ 371 Date: Nov. 23, 2022

(30) Foreign Application Priority Data
May 25, 2020 (JP) 2020-090547

(51) Int. Cl. H01L 33/60; H01L 33/48; H01L 25/16

(52) U.S. Cl. CPC H01L 33/60; H01L 33/483; H01L 25/167

(57) ABSTRACT

A light-emitting device includes a component-mounting body including a first surface including a recess, and a light emitter mounted in the recess. The component-mounting body allows at least part of light emitted from the light emitter to be reflected from an inner peripheral surface of the recess at least twice.

### TECHNICAL FIELD

The present disclosure relates to a light-emitting device and a display device.

### BACKGROUND OF INVENTION

A known light-emitting device is described in, for example, Patent Literature 1.

### CITATION LIST

### Patent Literature

Patent Literature 1: Japanese Unexamined Patent Application Publication No. 2013-8941

### SUMMARY

In an aspect of the present disclosure, a light-emitting device includes a component-mounting body including a first surface including a recess, and a light emitter located in the recess. The component-mounting body allows at least part of light emitted from the light emitter to be reflected from an inner peripheral surface of the recess at least twice.

In an aspect of the present disclosure, a light-emitting device includes a component-mounting body including a first surface including a recess, and a light emitter located in the recess. The recess has an opening area of more than one time but not more than 1.5 times a bottom surface area of the recess, and a depth of at least 2.5 times an absolute value of a square root of the bottom surface area.

In an aspect of the present disclosure, a display device includes a plurality of the light-emitting devices according to any one of the above aspects. The plurality of light-emitting devices is arranged in a matrix.

### BRIEF DESCRIPTION OF THE DRAWINGS

The objects, features, and advantages of the present disclosure will become more apparent from the following detailed description and the drawings.

FIG. 1 is a plan view of a light-emitting device according to an embodiment of the present disclosure.

FIG. 2 is a cross-sectional view taken along line A1-A2 in FIG. 1.

FIG. 3 is a graph showing the angular distribution of radiant intensity of light emitted from a light-emitting diode (LED).

FIG. 4 is a cross-sectional view of a light-emitting device according to a variation of the embodiment of the present disclosure.

FIG. 5 is a cross-sectional view of a light-emitting device according to a variation of the embodiment of the present disclosure.

FIG. 6 is a plan view of a display device according to an embodiment of the present disclosure.

FIG. 7 is a cross-sectional view taken along line B1-B2 in FIG. 6.

FIG. 8 is a cross-sectional view of a display device according to another embodiment of the present disclosure, corresponding to FIG. 2.

FIG. 9 is a cross-sectional view of a display device according to another embodiment of the present disclosure, corresponding to FIG. 2.

FIG. 10 is a cross-sectional view of a display device according to another embodiment of the present disclosure, corresponding to FIG. 2.

FIG. 11 is a cross-sectional view of a display device according to another embodiment of the present disclosure, corresponding to FIG. 2.

FIG. 12 is a cross-sectional view of a display device according to another embodiment of the present disclosure, corresponding to FIG. 2.

### DESCRIPTION OF EMBODIMENTS

The structure that forms the basis of a light-emitting device according to one or more embodiments of the present disclosure will be described. In a known light-emitting device described in Patent Literature 1, a light emitter and a frame-shaped reflective member surrounding the light emitter are located on one main surface of a substrate. The light emitter such as a light-emitting diode (LED) may have light distribution characteristics with which the angular distribution of radiant intensity of light is not the highest in a direction perpendicular to the light-emitting surface. A known light-emitting device including a light emitter with such light distribution characteristics may have low directivity of emission light. For a display device including multiple light-emitting devices arranged in a matrix, light emitted from the light-emitting devices that are located close to one another may interfere with one another. This may degrade the image quality of the display device.

A light-emitting device and a display device according to one or more embodiments of the present disclosure will now be described with reference to the accompanying drawings. Each figure referred to below illustrates main components and other elements of the light-emitting device and the display device according to one or more embodiments of the present disclosure. The light-emitting device and the display device according to the embodiments of the present disclosure may include known components not illustrated in the figures, such as circuit boards, wiring conductors, control integrated circuits (ICs), and large-scale integration (LSI) circuits.

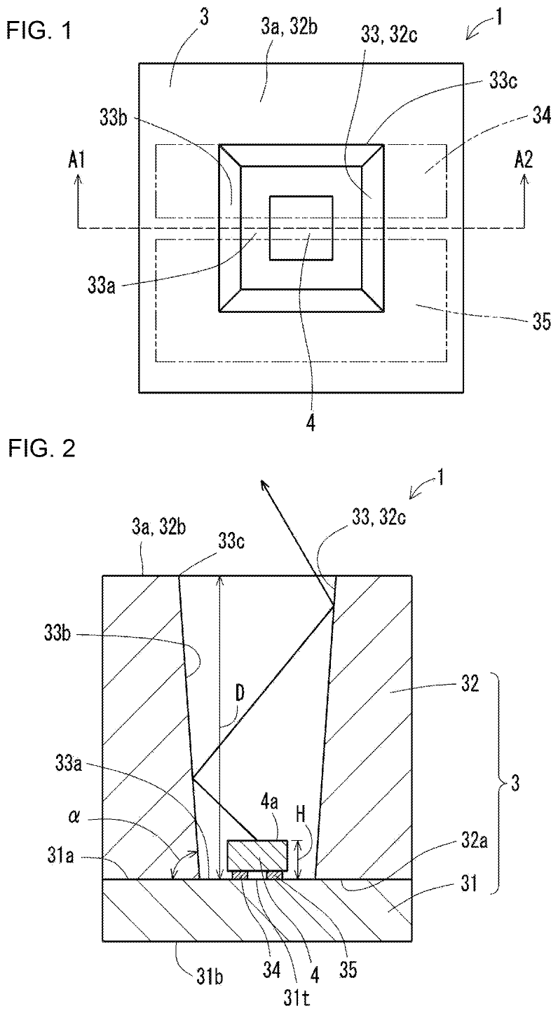

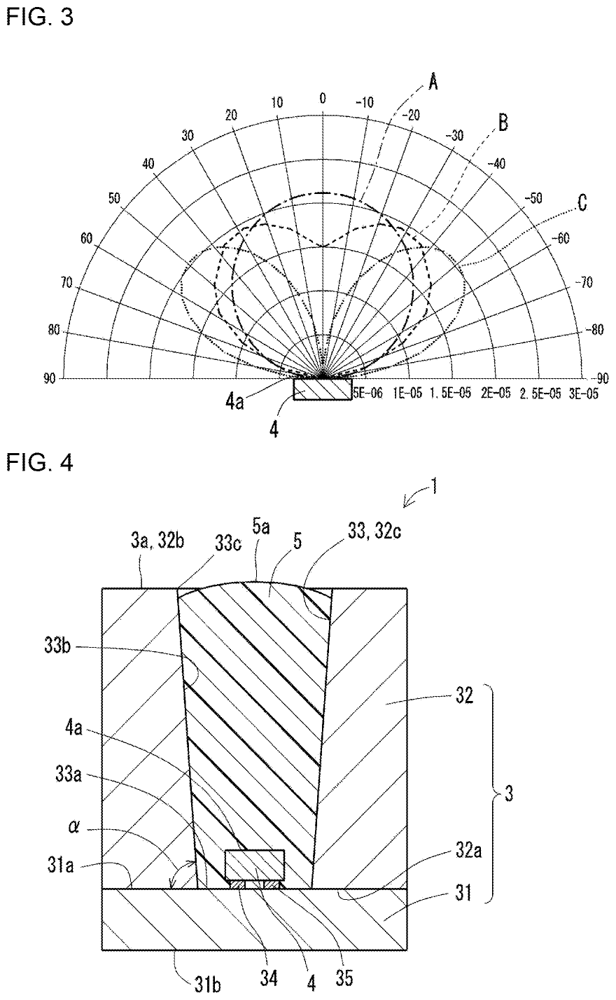

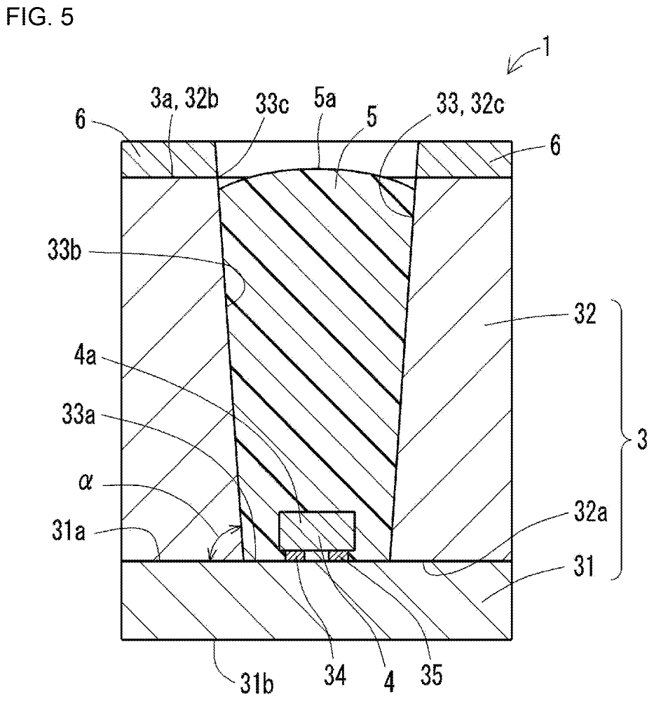

FIG. 1 is a plan view of a light-emitting device according to an embodiment of the present disclosure. FIG. 2 is a cross-sectional view taken along line A1-A2 in FIG. 1. FIG. 3 is a graph showing the angular distribution of radiant intensity of light emitted from an LED. FIGS. 4 and 5 are cross-sectional views of light-emitting devices according to variations of the embodiment of the present disclosure. FIG. 3 shows three examples of radiant intensity (W/sr: watts/steradian) distribution patterns of light emitted from an LED. The radiant intensity of light (W/sr) is the radiant energy (radiant flux) emitted from a point source in a certain direction per unit time per unit solid angle. The cross-sectional views of FIGS. 4 and 5 correspond to the cross-sectional view of FIG. 2.

A light-emitting device 1 according to the present embodiment includes a component-mounting body 3 and a light emitter 4.

The component-mounting body 3 includes a first surface 3a through which light is emitted. The component-mounting body 3 is, for example, a plate or a block. The component-mounting body 3 may be, for example, triangular, square, rectangular, trapezoidal, hexagonal, circular, oval, or in any other shape as viewed in plan (in other words, as viewed in a direction perpendicular to the first surface 3a). The component-mounting body 3 is made of, for example, an electrically insulating material such as a glass material, a ceramic material, or a resin material, a metal material, or a semiconductor material such as silicon. The component-mounting body 3 may include layers or plates of any of the above materials stacked on one another. The layers or plates may be made of materials different from one another.

The component-mounting body 3 may include a substrate 31 as a first substrate including a mount 31t for mounting the light emitter 4, and a recess member 32 as a second substrate located on the substrate 31 and including a through-hole 32c extending from the first surface 3a to a second surface 32a opposite to the first surface 3a, which is on the substrate 31. The recess 33 may include the through-hole 32c and the mount 31t located in the through-hole 32c. In this structure, the recess member 32 defining the recess 33 is separate from the substrate 31, thus facilitating adjustment of the depth of the recess 33 to an intended depth. In a known structure, for example, a recess is formed in a resin layer directly formed on a substrate 31 by photolithography. The depth of the recess is substantially less than or equal to the height of the light emitter 4. The depth of the recess thus cannot easily be greater than the height of the light emitter 4. The above structure responds to this issue.

The first substrate may be, for example, a plate or a block, and may be triangular, square, rectangular, trapezoidal, hexagonal, circular, oval, or in any other shape as viewed in plan. The first substrate may be made of an electrically insulating material such as a glass material, a ceramic material, or a resin material, a metal material, or a semiconductor material such as silicon. The first substrate may include multiple layers or plates of any of the above materials stacked on one another. The layers or plates may be made of materials different from one another. The second substrate may have the same or similar structure to the first substrate.

The first surface 3a of the component-mounting body 3 includes the recess 33 in which the light emitter 4 is located. The light emitter 4 is, for example, mounted on a bottom surface 33a of the recess 33 and located on the bottom surface 33a. As illustrated in FIG. 2, for example, the recess 33 is open on the first surface 3a and recessed in the thickness direction of the component-mounting body 3. The recess 33 includes the bottom surface 33a and an inner peripheral surface 33b connecting the bottom surface 33a with the first surface 3a. The bottom surface 33a may be substantially parallel to the first surface 3a.

The opening of the recess 33 may be, for example, square, rectangular, hexagonal, circular, oval, or in any other shape. In the recess 33, the outer edge of an opening 33c may surround the outer edge of the bottom surface 33a in a plan view as illustrated in, for example, FIG. 1. In other words, the recess 33 may have cross sections parallel to the first surface 3a that gradually decrease in the depth direction, as illustrated in FIG. 2, for example. This structure facilitates output of light emitted from the light emitter 4 from the component-mounting body 3.

The light emitter 4 is mounted in the recess 33. The light emitter 4 may be mounted on the bottom surface 33a of the recess 33 with a light-emitting surface 4a facing the opening 33c of the recess 33. The light emitter 4 may be, for example, a self-luminous element such as an LED, an organic LED (OLED), or a semiconductor laser diode (LD). In the present embodiment, the light emitter 4 is an LED. The LED may be a micro-LED. The micro-LED mounted in the recess 33 may be rectangular as viewed in plan with each side having a length of about 1 to 100 μm inclusive, or about 5 to 20 μm inclusive.

The component-mounting body 3 includes an anode electrode 34 and a cathode electrode 35 located on the bottom surface 33a of the recess 33. The anode electrode 34 is electrically connected to an anode terminal of the light emitter 4. The cathode electrode 35 is electrically connected to a cathode terminal of the light emitter 4. The anode electrode 34 and the cathode electrode 35 are connected to a drive circuit (not illustrated) for controlling, for example, the emission or non-emission state and the light intensity of the light emitter 4.

The drive circuit includes, for example, a thin-film transistor (TFT) and a wiring conductor. The TFT may include, for example, a semiconductor film (or a channel) of amorphous silicon (a-Si) or low-temperature polycrystalline silicon (LTPS), and three terminals that are a gate electrode, a source electrode, and a drain electrode. The TFT serves as a switching device that switches conduction and non-conduction between the source electrode and the drain electrode based on the voltage applied to the gate electrode. The drive circuit may be located on the substrate 31, or between multiple insulating layers of, for example, silicon oxide (SiO₂) or silicon nitride (Si₃N₄) located on the substrate 31. The drive circuit may be formed by a thin film formation method such as chemical vapor deposition (CVD).

The light emitter 4 may be electrically and mechanically connected to the anode electrode 34 and the cathode electrode 35 by flip chip connection using a conductive connector, such as an anisotropic conductive film (ACF), a solder ball, a metal bump, or a conductive adhesive. The light emitter 4 may be electrically and mechanically connected to the anode electrode 34 and the cathode electrode 35 using a conductive connector such as a bonding wire.

The light emitter 4 may be a prism, a cylinder, a cone, a pyramid, or in any other shape including an upper surface and a side surface, and may emit light from the upper surface and the side surface. When the light emitter 4 is, for example, an LED, the directivity of radiant intensity may be low, as indicated by radiant intensity distribution patterns A, B, and C in FIG. 3. In the radiant intensity distribution of the light emitter 4, the radiant intensity may not be maximum in a direction frontward from the light-emitting surface 4a (upward direction in FIG. 2), as in the radiant intensity distribution patterns B and C. More specifically, the direction of maximum radiant intensity may be inclined with respect to the direction upward (straight upward) from the light emitter 4. In other words, the direction of maximum radiant intensity may be a direction inclined with respect to the normal direction of the light-emitting surface 4a that is the upper surface of the light emitter 4 (this normal direction may be the normal direction of the bottom surface 33a of the recess 33). The inventor has noticed that, for the light emitter 4 with a radiant intensity distribution pattern as shown in FIG. 3, or more specifically, a radiant intensity distribution pattern B or C, the directivity of emission light from the light emitter 4 is reduced when most of the emission light is emitted outside after either no reflection occurs or reflection occurs once from the inner peripheral surface 33b of the recess 33. The inventor has also noticed that, also for the light emitter 4 with a radiant intensity distribution pattern as shown in FIG. 3, the directivity of emission light from the light emitter 4 is increased effectively when most of the emission light is emitted outside after reflection occurs from the inner peripheral surface 33b at least twice.

In the light-emitting device 1, at least part of light emitted from the light emitter 4 is reflected from the inner peripheral surface 33b of the recess 33 in the component-mounting body 3 at least twice. This structure allows the radiant intensity distribution of the light emitted outside from the recess 33 to be a highly directional pattern of a longitudinally oblong shape approximate to a cosine (cos θ) surface, with the maximum intensity direction substantially aligning with the normal direction of the first surface 3a and the bottom surface 33a of the recess 33. In other words, the radiant intensity distribution of light emitted outside from the recess 33 has a highly directional pattern of a longitudinally oblong shape approximate to a cosine surface, which follows Lambert's cosine law (the law by which the radiant intensity of light observed from an ideal diffuse radiator is directly proportional to the cosine of the angle θ between the direction of the incident light and the normal of the radiating surface, or the first surface 3a and the bottom surface 33a of the recess 33 in the light-emitting device 1 according to the present embodiment). A cosine surface herein refers to a radiant intensity distribution pattern in the shape of a cosine curve as viewed in a longitudinal section.

When the frontal luminance (luminance measured at the front of the light-emitting device 1) of a light-emitting device 1 without the recess 33 is normalized to 1.0, this structure allows the frontal luminance with the recess 33 to be about at least 1.5 to 2.0 times higher. This further allows the frontal luminance to be about at least 1.5 to 2.0 times higher but not more than 5 times higher.

When an angle θ1 (also referred to as a recess emission angle) is defined as the angle including at least 50% of the total radiant intensity in the radiant intensity distribution of the light emitted outside from the recess 33, the angle θ1 may be less than or equal to a predetermined angle. The predetermined angle is set depending also on the radiant intensity distribution of the light emitter 4. The predetermined angle may be, for example, 30°, 20° or 10°.

At least part of light reflected from the inner peripheral surface 33b of the recess 33 at least twice may include light emitted in the direction of maximum radiant intensity in the radiant intensity distribution of the light emitter 4. This increases the amount of light emitted in directions less than or equal to the recess emission angle θ1, further increasing the directivity of the light emitted from the recess 33. The direction of the maximum radiant intensity of the light emitter 4 may be inclined by a predetermined angle (e.g., 5 to 60°) with respect to the direction upward from the light emitter 4. When an angle θ2 is formed between the direction of maximum radiant intensity in the radiant intensity distribution of the light emitter 4 and the normal of the bottom surface 33a of the recess 33, the angle θ2 may be about 20 to 60° or about 30 to 50°. This increases the likelihood of most of the light emitted from the light emitter 4, or for example, at least 50% of the total amount of light, being reflected from the inner peripheral surface 33b of the recess 33 at least twice.

At least part of light reflected from the inner peripheral surface 33b of the recess 33 at least twice may include at least 50% of the total amount of light emitted from the light emitter 4. This further increases the amount of light emitted in directions less than or equal to the recess emission angle θ1, further increasing the directivity of the light emitted from the light-emitting device 1.

The depth of the recess 33 may be at least twice but not more than 15 times the height of the light-emitting surface 4a of the light emitter 4 from the bottom surface 33a. This facilitates the recess 33 to have a depth appropriate to allow at least part of light emitted from the light emitter 4 to be reflected from the inner peripheral surface 33b of the recess 33 at least twice. With the depth less than twice the height, the recess 33 is likely to be too shallow to allow at least part of light emitted from the light emitter 4 to be reflected from the inner peripheral surface 33b of the recess 33 at least twice. With the depth more than 15 times the height, at least part of light emitted from the light emitter 4 is likely to be reflected from the inner peripheral surface 33b of the recess 33, for example, more than 5 times, thus lowering the intensity (luminance) of light emitted from the recess 33. The depth of the recess 33 may be at least 3 times but not more than 15 times the height of the light-emitting surface 4a of the light emitter 4 from the bottom surface 33a.

The inner peripheral surface 33b of the recess 33 may be light-reflective. This reduces the likelihood of the amount of reflected light decreasing when the inner peripheral surface 33b of the recess 33 reflects at least part of light emitted from the light emitter 4 at least twice, as described later. This reduces the likelihood that the amount of light emitted outside from the recess 33 decreases. In the above structure, the recess member 32 may be made of a highly light-reflective material such as aluminum. For the recess member 32 made of a material with low light reflectivity, such as a glass material, a ceramic material, or a resin material, a light reflecting layer, such as an aluminum layer, may be located on the inner peripheral surface 33b of the recess 33.

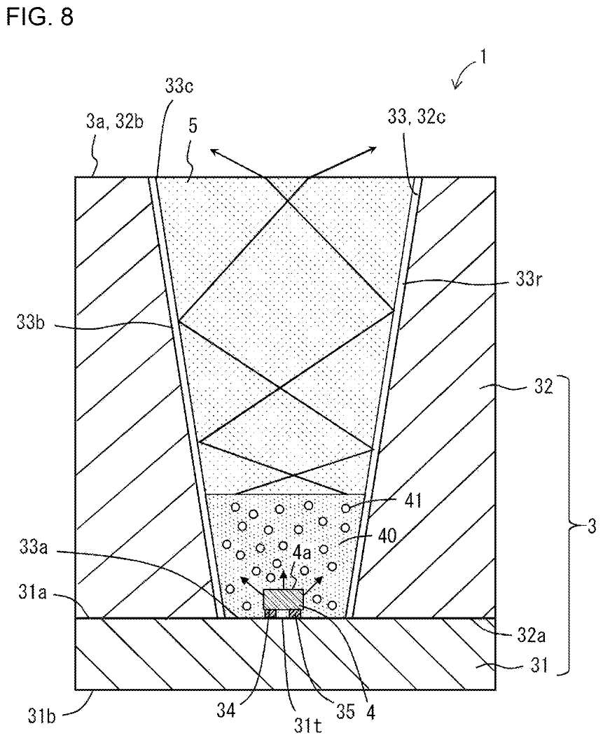

As illustrated in FIG. 8, the recess 33 may include a light-transmissive member 40 including light scatterers 41 to allow at least part of light emitted from the light emitter 4 passing through the light-transmissive member 40 to be reflected from the inner peripheral surface of the recess 33 at least twice. The light-transmissive member 40 may be made of, for example, a resin material such as a silicone resin, an acrylic resin, a polycarbonate resin, or an epoxy resin. The light-transmissive member 40 may be formed by placing the above resin material in the recess 33 and curing the material by, for example, a photo-curing method of irradiating the material with light such as ultraviolet rays, a thermal curing method of curing the material at a predetermined temperature, or a photothermal curing method. The light-transmissive member 40 may be made of a glass material. In this case, the light-transmissive member 40, which is shaped to fit into the recess 33, may be placed in the recess 33 and bonded to the inner peripheral surface 33b of the recess 33 with a transparent adhesive. The light-transmissive member 40 may cover the light emitter 4. This allows the light emitted from the side surface of the light emitter 4 to be effectively scattered by the light scatterers 41 and the wavelength to be effectively converted by light wavelength converters included in the light scatterers 41. The light scatterers 41 may be light-scattering particles of a glass material, a resin material, or a ceramic material. The average diameter of the light-scattering particles may be about 10 nm to 100 μm, but the range is not limited to this.

With the light-transmissive member 40 including the light scatterers 41, light emitted from the light-transmissive member 40 is likely to have a radiant intensity distribution close to Lambert's cosine law. In other words, in the radiant intensity distribution of light emitted from the light-transmissive member 40, the direction in which the radiant intensity is maximum (hereafter also referred to as the maximum radiation direction) is likely to be close to a direction orthogonal to the light-emitting surface 4a of the light emitter 4. This reduces the likelihood of the light emitted in the maximum radiation direction from the light-transmissive member 40 being reflected from the inner peripheral surface 33b of the recess 33 excess times (number of reflections). The number of reflections exceeding, for example, five, can cause the light emitted outside from the recess 33 to attenuate.

The light scatterers 41 may include light wavelength converters. In other words, some or all of the light scatterers 41 may be light wavelength converters. The light wavelength converters may be phosphors or quantum dots. The phosphors or quantum dots may be uniformly dispersed in the light-transmissive member 40. The phosphor material may be, for example, an organic phosphor material such as a cyanine dye, a pyridine dye, or a rhodamine dye, or an inorganic phosphor material such as (Sr, Ca)AlSiN₃:Eu, Y₂O₂S:Eu, or Y₂O₃:Eu. The symbol:Eu refers to Eu being contained as a trace component. Quantum dots are particles with diameters of about 1 to 100 nm inclusive. Examples of materials of quantum dots include CdSe, CdS, and InP. A light-transmissive member 40 including quantum dots improves the color purity of light emitted from the light-transmissive member 40.

As illustrated in FIG. 8, a light reflecting layer 33r of, for example, aluminum (Al) may be located on the inner peripheral surface 33b of the recess 33. In the recess 33, as viewed from the light emitter 4, the light-transmissive member 40 and a seal 5 may be located in this order. The recess 33 may be with no seal 5 and filled with the light-transmissive member 40.

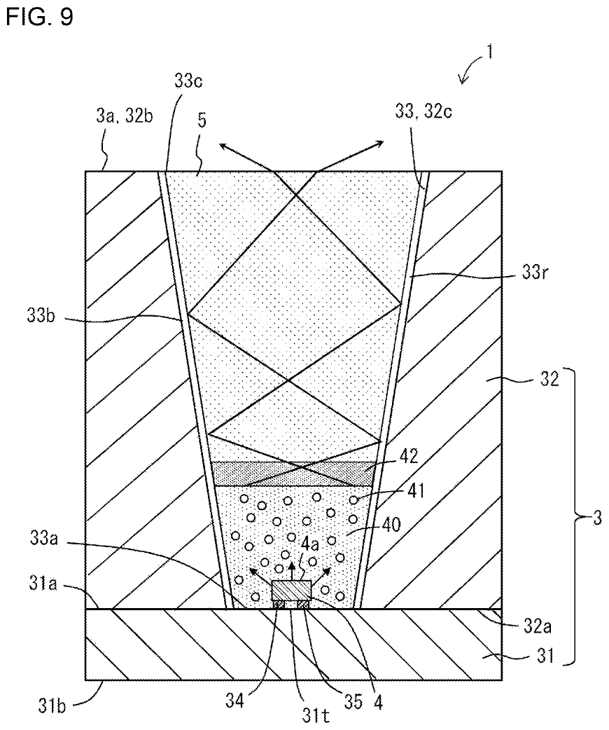

As illustrated in FIG. 9, in the recess 33, as viewed from the light emitter 4, the light-transmissive member 40, a color filter layer 42, and the seal 5 may be located in this order. The color filter layer 42 is located, for example, to absorb and cut off excitation light (emission light from the light emitter 4) with its wavelength not being converted by the light scatterers 41 including the light wavelength converters, reducing the excitation light emitted outside from the recess 33.

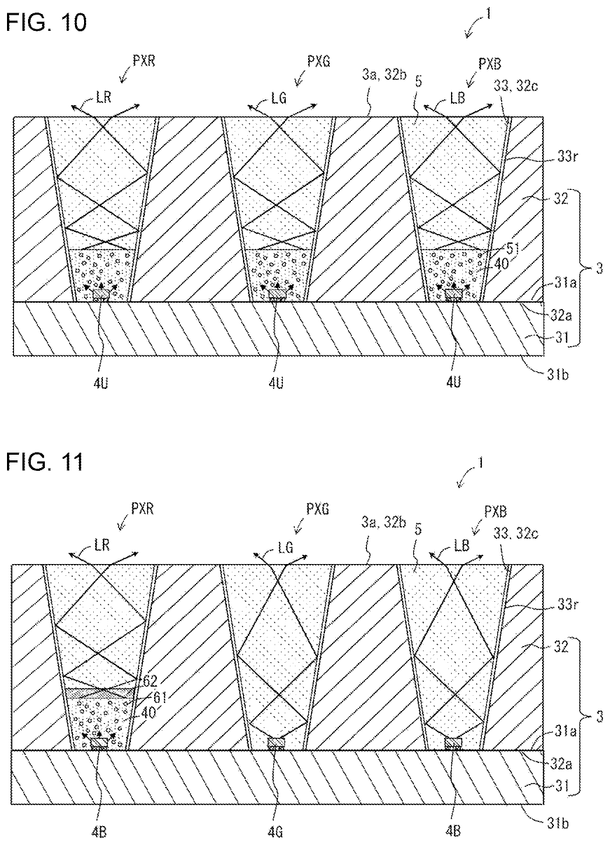

As illustrated in FIG. 10, one pixel may include three subpixels. The three subpixels are a subpixel PXR that emits red light LR, a subpixel PXG that emits green light LG, and a subpixel PXB that emits blue light LB. The subpixel PXR includes a light emitter 4U emitting ultraviolet light and located on a mount on the bottom surface of a recess 33 including a light reflecting layer 33r on the inner peripheral surface of the recess 3, a light-transmissive member 40 that covers the light emitter 4U, light scatters 41 as light wavelength converters that are included in the light-transmissive member 40 and convert ultraviolet light to red light, and a seal 5. The subpixel PXG includes light scatterers 41 as light wavelength converters that convert ultraviolet light to green light, and includes other components that are the same as or similar to those of the subpixel PXR. The subpixel PXB includes light scatterers 41 as light wavelength converters that convert ultraviolet light to blue light, and includes other components that are the same as or similar to those of the subpixel PXR. In FIG. 10, the structure of a pixel is simplified with the subpixels PXR, PXG, and PXB differing from one another simply in the type of the light scatterers 41. This structure also eliminates a light emitter emitting red light, which uses a large drive current to allow high-gradation display because of its luminous intensity (luminance) varying less widely relative to the drive current than in light emitters 4U, 4G, and 4B. This thus reduces current consumption. Using one type of light emitters 4U alone also simplifies the drive circuit structure.

As illustrated in FIG. 11, one pixel may include three subpixels PXR, PXG, and PXB. The subpixel PXR includes a light emitter 4B emitting blue light and located on a mount on the bottom surface of a recess 3 including a light reflecting layer 33r on the inner peripheral surface of the recess 3, a light-transmissive member 40 that covers the light emitter 4B, light scatters 61 as light wavelength converters that are included in the light-transmissive member 40 and convert blue light to red light, a color filter layer 62 located on the light-transmissive member 40, and a seal 5. The subpixel PXG includes a light emitter 4G that emits green light and a seal 5, but does not include a light-transmissive member 40 or a color filter layer. The subpixel PXB includes a light emitter 4B that emits blue light and a seal 5, but does not include a light-transmissive member 40 or a color filter layer. In FIG. 11, the structure of a pixel is simplified using two types of light emitters 4B and 4G and two types of internal structures of the recesses 33. This structure also eliminates a light emitter emitting red light, which uses a large drive current to allow high-gradation display because of its luminous intensity (luminance) varying less widely relative to the drive current than in light emitters 4G and 4B. This thus reduces current consumption. Using two types of light emitters 4G and 4B also simplifies the drive circuit structure.

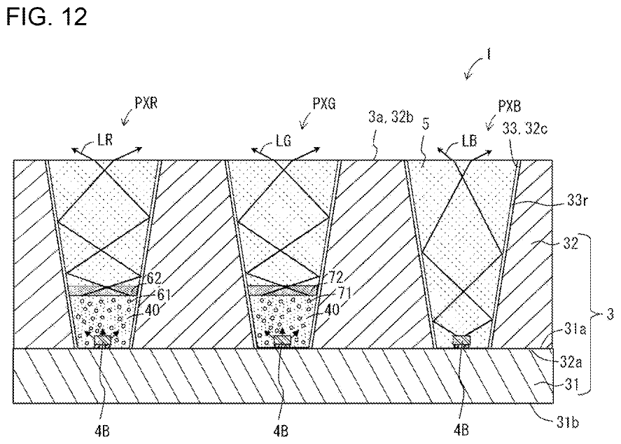

As illustrated in FIG. 12, one pixel may include three subpixels PXR, PXG, and PXB. The subpixel PXR includes a light emitter 4B emitting blue light and located on a mount on the bottom surface of a recess 33 including a light reflecting layer 33r on the inner peripheral surface of the recess 3, a light-transmissive member 40 that covers the light emitter 4B, light scatters 61 as light wavelength converters that are included in the light-transmissive member 40 and convert blue light to red light, a color filter layer 62 located on the light-transmissive member 40, and a seal 5. The subpixel PXG includes light scatterers 71 as light wavelength converters that convert blue light to green light and a color filter layer 72 located on the light-transmissive member 40, and other components that are the same as or similar to those of the subpixel PXR. The subpixel PXB includes a light emitter 4B that emits blue light and a seal 5, but does not include a light-transmissive member 40 or a color filter layer. In FIG. 12, the structure of a pixel is simplified using one type of light emitters 4B and two types of internal structures of the recesses 33. This structure also eliminates a light emitter emitting red light, which uses a large drive current to allow high-gradation display because of its luminous intensity (luminance) varying less widely relative to the drive current than in light emitters 4G and 4B. This thus reduces current consumption. Using one type of light emitters 4B alone also simplifies the drive circuit structure.

In the light-emitting device 1, an opening area Sc of the recess 33 may be more than one time but not more than 1.5 times a bottom surface area Sa of the recess 33, and a depth D of the recess 33 may be at least 2.5 times the absolute value of the square root of the bottom surface area Sa. This allows emission light from the light emitter 4 to be reflected from the inner peripheral surface 33b at least twice in the light emitter 4 having a radiant intensity distribution pattern as shown in FIG. 3, or more specifically, a radiant intensity distribution pattern B or C. The recess emission angle θ1 may thus be less than or equal to a predetermined angle. This also increases the directivity of light emitted from the light-emitting device 1. The depth D of the recess 33 refers to the depth of the recess 33 in the thickness direction of the component-mounting body 3 (normal direction of the first surface 3a).

In the light-emitting device 1, the maximum diameter of the opening of the recess 33 may be more than one time but not more than 1.5 times the maximum diameter of the bottom surface of the recess 33, and the depth D of the recess 33 may be at least 2.5 times the absolute value of the square root of the bottom surface area Sa. This increases the ratio of the opening area Sc of the recess 33 to the bottom surface area Sa of the recess 33 compared with the above structure, allowing emission light from the light emitter 4 to be reflected from the inner peripheral surface 33b at least twice and the viewing angle of the display of the light-emitting device 1 to be wider. The maximum diameter of the opening of the recess 33 is, for example, the diameter of a circular opening of the recess 33, the major axis of an elliptic opening of the recess 33, or the maximum diagonal length of a rectangular opening of the recess 33. The same applies to the maximum diameter of the bottom surface of the recess 33.

In the recess 33, the depth D may be greater than or equal to 30 μm and the inclination angle of the inner peripheral surface 33b to the bottom surface 33a may be greater than or equal to 65°. In the light emitter 4, a height H of the light-emitting surface 4a from the bottom surface 33a may be 2 to 15 μm inclusive, or 2 to 10 μm inclusive. This increases the amount of light emitted in directions less than or equal to the recess emission angle θ1, further increasing the directivity of the light emitted from the light-emitting device 1. The inclination angle of the inner peripheral surface 33b with respect to the bottom surface 33a may be, for example, an angle α (illustrated in FIG. 2) between the bottom surface 33a and the inner peripheral surface 33b as viewed in the longitudinal section of the component-mounting body 3. The longitudinal section may be, for example, a section of the component-mounting body 3 cut through the centroid of the bottom surface 33a and perpendicular to the first surface 3a. When the angle α varies depending on the longitudinal section taken, the minimum value of the angle α in the longitudinal sections taken in varied manners may be defined as the inclination angle. The inclination angle may be the angle between the normal of the bottom surface 33a and the normal of the inner peripheral surface 33b.

In the light-emitting device 1 according to the present embodiment, the component-mounting body 3 includes the substrate 31 and the recess member 32, as illustrated in, for example, FIG. 2. The substrate 31 is a flat plate and includes one main surface 31a. The recess member 32 is a plate and is located on one main surface 31a. The recess member 32 includes the second surface 32a facing one main surface 31a, and a third surface 32b opposite to the second surface 32a. The recess member 32 includes the first surface 3a of the component-mounting body 3. The third surface 32b of the recess member 32 may be the first surface 3a of the component-mounting body 3. The third surface 32b may also be hereafter referred to as the first surface 3a.

The recess member 32 includes the through-hole 32c extending from the first surface 3a to the second surface 32a facing one main surface 31a. The through-hole 32c exposes a portion of one main surface 31a of the substrate 31, and the exposed portion is the bottom surface 33a of the recess 33. The inner peripheral surface of the through-hole 32c is the inner peripheral surface 33b of the recess 33.

The substrate 31 is made of, for example, a glass material, a ceramic material, a resin material, a metal material, or a semiconductor material. Examples of the glass material used for the substrate 31 include borosilicate glass, crystallized glass, and quartz. Examples of the ceramic material used for the substrate 31 include alumina (Al₂O₃), zirconia (ZrO₂), silicon nitride (Si₃N₄), silicon carbide (SiC), and aluminum nitride (AlN). Examples of the resin material used for the substrate 31 include an epoxy resin, a polyimide resin, and a polyamide resin.

Examples of the metal material used for the substrate 31 include aluminum (Al), titanium (Ti), beryllium (Be), magnesium (Mg) (specifically, chemically stable, high-purity magnesium with Mg content of 99.95 mass % or higher), zinc (Zn), tin (Sn), copper (Cu), iron (Fe), chromium (Cr), nickel (Ni), and silver (Ag). Examples of an alloy material used for the substrate 31 include duralumin, which is an aluminum alloy containing aluminum as a main component (an Al—Cu alloy, an Al—Cu—Mg alloy, or an Al—Zn—Mg—Cu alloy), a magnesium alloy containing magnesium as a main component (a Mg—Al alloy, a Mg—Zn alloy, or a Mg—Al—Zn alloy), titanium boride, stainless steel, and a Cu—Zn alloy. Examples of the semiconductor material used for the substrate 31 include silicon, germanium, and gallium arsenide. For the substrate 31 made of a metal material or a semiconductor material, an insulating layer of, for example, silicon oxide (SiO₂) or silicon nitride (Si₃N₄) may be located on at least one main surface 31a, and the light emitter 4 may be located on the insulating layer. This prevents electrical short-circuiting between the anode terminal and the cathode terminal of the light emitter 4.

The substrate 31 may include a drive circuit for controlling, for example, the emission or non-emission state and the light intensity of the light emitter 4. The drive circuit may be located on one main surface 31a or the other main surface 31b of the substrate 31. For the drive circuit being a TFT that includes a semiconductor film of LTPS on the substrate 31 made of a glass material, the drive circuit may be formed directly by a thin film formation method such as CVD.

The recess member 32 is made of, for example, a glass material, a ceramic material, a resin material, a metal material, or a semiconductor material. Examples of the glass material used for the recess member 32 include borosilicate glass, crystallized glass, and quartz. Examples of the ceramic material used for the recess member 32 include alumina, zirconia, silicon nitride, silicon carbide, and aluminum nitride. Examples of the resin material used for the substrate 31 include an epoxy resin, a polyimide resin, and a polyamide resin. Examples of the metal material used for the recess member 32 include aluminum (Al), titanium (Ti), beryllium (Be), magnesium (Mg) (specifically, chemically stable, high-purity magnesium with Mg content of 99.95 mass % or higher), zinc (Zn), tin (Sn), copper (Cu), iron (Fe), chromium (Cr), nickel (Ni), silver (Ag), molybdenum (Mo), and tungsten (W). Examples of an alloy material used for the recess member 32 include duralumin, which is an aluminum alloy containing aluminum as a main component (an Al—Cu alloy, an Al—Cu—Mg alloy, or an Al—Zn—Mg—Cu alloy), a magnesium alloy containing magnesium as a main component (a Mg—Al alloy, a Mg—Zn alloy, or a Mg—Al—Zn alloy), titanium boride, stainless steel, and a Cu—Zn alloy. Examples of the semiconductor material used for the recess member 32 include silicon, germanium, and gallium arsenide.

The recess member 32 may include a single layer of the glass material, the ceramic material, the resin material, the metal material, or the semiconductor material described above, or may be a stack of multiple layers of the glass material, the ceramic material, the resin material, the metal material, or the semiconductor material described above stacked on one another. For the recess member 32 made of a metal material, the recess member 32 may be connected to the substrate 31 with an insulating layer of, for example, silicon oxide (SiO₂) or silicon nitride (Si₃N₄) or an insulating member made of a resin material in between.

For the recess member 32 made of a glass material, the through-hole 32c may be formed by, for example, photolithography. For the recess member 32 made of a ceramic material, a powder of a raw ceramic material is mixed with an appropriate organic binder and an appropriate solvent to form slurry. The slurry is then shaped into a sheet using a known method such as doctor blading or calendering to form a ceramic green sheet (hereafter also referred to as a green sheet). The green sheet is then punched into a predetermined shape including a hole to be the through-hole 32c. The recess member 32 including a through-hole 32c can be fabricated by stacking multiple punched green sheets and fire them together at a temperature of about 1600° C. For the recess member 32 made of a resin material, the recess member 32 including the through-hole 32c can be fabricated by, for example, injection molding. For the recess member 32 made of a metal material, the recess member 32 including the through-hole 32c can be fabricated by, for example, punching or electroforming (plating). For the recess member 32 made of a semiconductor material, the recess member 32 including the through-hole 32c can be fabricated by, for example, dry etching.

In the recess member 32, at least the inner peripheral surface 33b of the recess 33 may be light-reflective. This reduces the likelihood of the amount of reflected light decreasing when at least part of light emitted from the light emitter 4 is reflected from the inner peripheral surface 33b of the recess 33 at least twice. This reduces the likelihood that the amount of light emitted outside from the recess 33 decreases. For the recess member 32 made of a material with low light reflectivity, such as a glass material, a ceramic material, or a resin material, a light reflecting layer may be located on the inner peripheral surface 33b of the recess 33. The light reflecting layer may be a metal layer with high reflectance of visible light made of, for example, aluminum (Al), silver (Ag), gold (Au), chromium (Cr), nickel (Ni), platinum (Pt), tin (Sn), or an alloy layer with high reflectance of visible light made of, for example, duralumin (an Al—Cu alloy, an Al—Cu—Mg alloy, or an Al—Zn—Mg—Cu alloy), which is an aluminum alloy containing aluminum as a main component. These materials have light reflectance of about 90 to 95% for aluminum, 93% for silver, 60 to 70% for gold, 60 to 70% for chromium, 60 to 70% for nickel, 60 to 70% for platinum, 60 to 70% for tin, and 80 to 85% for an aluminum alloy.

The light reflecting layer may be formed on the inner peripheral surface 33b of the recess 33 by a thin film formation method such as CVD, vapor deposition, plating, or by a thick film formation method such as firing and solidifying a resin paste containing particles of any of the above metals or alloys. The light-reflecting layer may be formed by a bonding method of bonding a film of any of the above metals or alloys onto the inner peripheral surface 33b of the recess 33.

The light-emitting device 1 may include a light-transmissive seal 5 located in the recess 33 as illustrated in, for example, FIG. 4. The seal 5 may have insulating properties and may directly cover the light emitter 4. This reduces the likelihood of the light emitter 4 being misaligned or separate from the bottom surface 33a, thus improving the reliability of the light-emitting device 1. The seal 5 may be made of, for example, a resin material such as a silicone resin, an acrylic resin, a polycarbonate resin, or an epoxy resin, or a resin material containing light-scattering particles of, for example, a glass material, a resin material, or a ceramic material. The average diameter of the light-scattering particles may be about 10 nm to 100 μm, but the range is not limited to this. The seal 5 may be formed by placing the above resin material in the recess 33 and curing the material by, for example, a photo-curing method of irradiating the material with light such as ultraviolet rays, a thermal curing method of curing the material at a predetermined temperature, or a photothermal curing method. The seal 5 may be made of a glass material. In this case, the seal 5, which is shaped to fit into the recess 33, may be placed in the recess 33 and bonded to the inner peripheral surface 33b of the recess 33 with a transparent adhesive.

A front surface 5a of the seal 5 exposed outside may be flat or, as illustrated in FIG. 4, for example, may be a curved surface in an outward (upward in FIG. 4) convex shape. The front surface 5a of the seal 5 exposed outside, which is a curved surface in an outward convex shape, has the optical function of focusing the light reflected from the inner peripheral surface 33b of the recess 33 and directed outward.

The light-emitting device 1 may include a light absorber 6 located on the first surface 3a of the component-mounting body 3, as illustrated in FIG. 5. This reduces the likelihood of external light being reflected from the first surface 3a of the component-mounting body 3 and interfering with light emitted from the light emitter 4 and emitted outside from the recess 33. The light absorber 6 is formed by, for example, applying a photo-curing or thermosetting resin material containing a light-absorbing material to the first surface 3a and curing the material. The light-absorbing material may be, for example, an inorganic pigment. Examples of the inorganic pigment that may be used include a carbon pigment such as carbon black, a nitride pigment such as titanium black, a metal oxide pigment such as chromium-iron-cobalt (Cr—Fe—Co), copper-cobalt-manganese (Cu—Co—Mn), iron-cobalt-manganese (Fe—Co—Mn), and iron-cobalt-nickel-chromium (Fe—Co—Ni—Cr) pigments.

In the structure in FIG. 5, the light absorber 6 may include an uneven surface that absorbs incident light. The light absorber 6 may be, for example, a light-absorbing film. The light-absorbing film may be a black film formed by mixing a black pigment such as carbon black in a base material such as a silicone resin, and an unevenness with an arithmetic mean roughness of about 10 to 50 μm or 20 to 30 μm may be formed on the surface of the black film by, for example, a transfer method. This structure greatly increases the light absorbing effect.

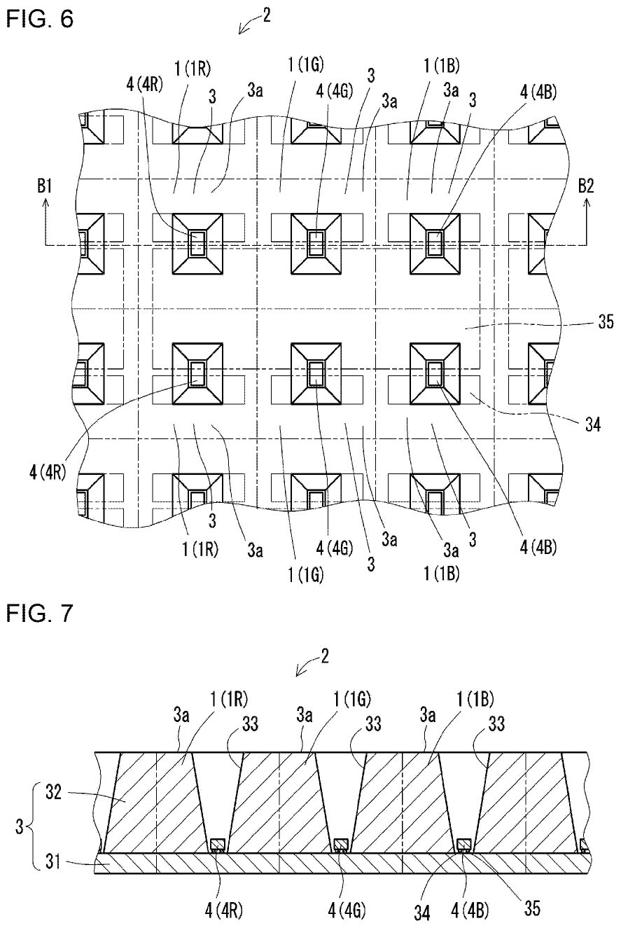

A display device according to an embodiment of the present disclosure will now be described. FIG. 6 is a plan view of a display device according to an embodiment of the present disclosure. FIG. 7 is a cross-sectional view taken along line B1-B2 in FIG. 6.

A display device 2 according to the present embodiment includes multiple light-emitting devices 1. The light-emitting devices 1 are arranged in a matrix in a single plane to form a composite display device (multi-display). The light-emitting devices 1 may be arranged with multiple first surfaces 3a of the component-mounting bodies 3 being on a single imaginary plane. The light-emitting devices 1 may be joined (tiled) to each other by joining the sides of every two adjacent light-emitting devices 1 with a bond such as an inorganic adhesive or an organic adhesive.

The display device 2 may include multiple component-mounting bodies 3 of multiple light-emitting devices 1 that are integral with one another. In other words, the display device 2 may include a single component-mounting body 3 including the first surface 3a including multiple recesses 33 each holding one of the multiple light emitters 4. The display device 2 may include multiple cathode electrodes 35 of the multiple light-emitting devices 1 that are integral with one another as a common cathode electrode.

The display device 2 may include multiple pixel units. Each pixel unit may include multiple light-emitting devices 1. The light-emitting devices 1 included in each pixel unit may be, for example, a light-emitting device 1R incorporating a light emitter 4R that emits red light, a light-emitting device 1G incorporating a light emitter 4G that emits green light, and a light-emitting device 1B incorporating a light emitter 4B that emits blue light. This allows the display device 2 to display full-color gradation.

Each pixel unit may include, in addition to the above light-emitting devices 1R, 1G, and 1B, at least one of a light-emitting device 1 that emits yellow light or a light-emitting device 1 that emits white light. This improves the color rendering and color reproduction of the display device 2. Each pixel unit may include, instead of the light-emitting device 1R that emits red light, a light-emitting device 1 that emits orange, red-orange, red-violet, or violet light. Each pixel unit may include, instead of the light-emitting device 1G that emits green light, a light-emitting device 1 that emits yellow-green light.

The display device 2 including the multiple light-emitting devices 1 with increased directivity of emission light reduces the likelihood of interference among emission light portions from multiple pixel units, thus improving image quality including luminance, contrast, gradation, and color rendering.

As described above, the light-emitting device according to the present disclosure increases the directivity of the emission light emitted from the light emitter and emitted from the component-mounting body. The display device according to the present disclosure further improves image quality, such as luminance, contrast, gradation, and color rendering.

Although the embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### INDUSTRIAL APPLICABILITY

The light-emitting device and the display device according to one or more embodiments of the present disclosure may be used for various electronic devices. Such electronic devices include lighting apparatus, automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, guidance display devices installed in stations or airports, and signage (digital signage) for advertisement.

### REFERENCE SIGNS

1, 1R, 1G, 1B light-emitting device
2 display device
3 component-mounting body
3a first surface
31 substrate
31a one main surface
31b the other main surface
31t mount
32 recess member
32a second surface
32b third surface
32c through-hole
33 recess
33a bottom surface
33b inner peripheral surface
33c opening
34 anode electrode
35 cathode electrode
4, 4R, 4G, 4B, 4U light emitter
4a light-emitting surface
5 seal
5a front surface
6 light absorber
40 light-transmissive member
41, 61, 71 light scatterer
42, 62, 72 color filter layer

1. A light-emitting device comprising:
a component-mounting body including a first surface including a recess; and
a light emitter located in the recess,
wherein the component-mounting body allows at least part of light emitted from the light emitter to be reflected from an inner peripheral surface of the recess at least twice.

2. The light-emitting device according to claim 1, wherein
the component-mounting body includes
a first substrate including a mount receiving the light emitter,
a second substrate located on the first substrate, the second substrate having a second surface which is opposite to the first surface and on the first substrate,
a through-hole extending from the first surface to the second surface, and
the recess includes the through-hole and the mount located in the through-hole.

3. The light-emitting device according to claim 1, wherein
the at least part of light includes light emitted in a direction of maximum radiant intensity in a radiant intensity distribution of the light emitter.

4. The light-emitting device according to claim 3, wherein
the direction of maximum radiant intensity is inclined with respect to a direction upward from the light emitter.

5. The light-emitting device according to claim 4, wherein
the direction of maximum radiant intensity is inclined by an angle of 5 to 60° with respect to the direction upward from the light emitter.

6. The light-emitting device according to claim 1, wherein
the at least part of light includes at least 50% of a total amount of light emitted from the light emitter.

7. The light-emitting device according to claim 1, wherein
the recess has a depth at least twice but not more than 15 times a height of a light-emitting surface of the light emitter from a bottom surface.

8. The light-emitting device according to claim 1, wherein
the recess includes the inner peripheral surface being light-reflective.

9. The light-emitting device according to claim 1, wherein
the recess includes a light-transmissive member including a light scatterer, and
the at least part of light emitted from the light emitter passes through the light transmissive member and is reflected from the inner peripheral surface of the recess at least twice.

10. The light-emitting device according to claim 9, wherein
the light scatterer includes a light wavelength converter.

11. A light-emitting device comprising:
a component-mounting body including a first surface including a recess; and
a light emitter located in the recess,
wherein the recess has an opening area of more than one time but not more than 1.5 times a bottom surface area of the recess, and a depth of at least 2.5 times an absolute value of a square root of the bottom surface area.

12. The light-emitting device according to claim 11, wherein
the recess has the depth greater than or equal to 30 μm and an inclination angle of an inner peripheral surface to a bottom surface greater than or equal to 65°, and
a height of a light-emitting surface of the light emitter from the bottom surface is 2 to 10 μm inclusive.

13. The light-emitting device according to claim 1, wherein
the component-mounting body includes
a substrate including one main surface, and
a recess member being a plate located on the one main surface and including the first surface,
the recess member further including a through-hole extending from the first surface to a second surface facing the one main surface and exposing a portion of the one main surface, and
the portion of the one main surface is a bottom surface of the recess, and an inner peripheral surface of the through-hole is the inner peripheral surface of the recess.

14. The light-emitting device according to claim 1, further comprising:
a light-transmissive seal located in the recess.

15. The light-emitting device according to claim 1, further comprising:
a light absorber on the first surface of the component-mounting body.

16. The light-emitting device according to claim 15, wherein
the light absorber includes an uneven surface to absorb incident light.

17. The light-emitting device according to claim 1, wherein
the light emitter includes a micro-light-emitting diode.

18. The light-emitting device according to claim 1, wherein
the light emitter includes an upper surface and a side surface, and emits light from the upper surface and the side surface.

19. A display device, comprising:
a plurality of the light-emitting devices according to claim 1,
wherein the plurality of light-emitting devices is arranged in a matrix.
